(19) United States
(12) Patent Application Publication
(10) Pub. No.: US 2015/0107644 A1
(43) Pub. Date: Apr. 23, 2015

(54) PHOTOVOLTAIC (PV) EFFICIENCY USING HIGH FREQUENCY ELECTRIC PULSES

(71) Applicant: UltraSolar Technology, Inc., Santa Clara, CA (US)

(72) Inventor: Santosh Kumar, San Jose, CA (US)

(21) Appl. No.: 14/449,000

(22) Filed: Jul. 31, 2014

Related U.S. Application Data
(60) Provisional application No. 61/891,899, filed on Oct. 17, 2013.

(51) Int. Cl. H01L 31/0525; H01L 31/065

(52) U.S. Cl. CPC H01L 31/058; H01L 31/065
USPC 136/244

(57) ABSTRACT

A system can include at least one solar cell comprising a semiconductor material having p-n junctions formed therein; and a pulse generator electrically coupled to the solar cell and configured to apply electric pulses to dynamically alter a band gap of the semiconductor material as photons are received by the semiconductor material.

This application claims the benefit of U.S. provisional patent application Ser. No. 61/891,899, filed on Oct. 17, 2013, the contents of which are incorporated by reference herein.

### TECHNICAL FIELD

The present disclosure relates generally to photovoltaic (PV) based solar cells, and particularly to the application of electric pulses to improve the power output of such solar cells.

### BACKGROUND

Solar cells are devices that produce electricity when subjected to light. Light photons create electrons and holes in solar cells. Electrons and holes are swept to electrodes by the electric field of p-n junctions formed by a semiconductor material within the solar cells. Electrons in the valance band require energy equivalent to band gap of the semiconductor to conduct by jumping from a valence band to a conduction band. Electrons in the conduction band contribute to the electricity generated by solar cells.

High energy photons can generate “hot” electrons which give up their energy in the form of heat and often do not contribute to electricity produced by the solar cell. Electrons which absorb high energy photons can become highly energetic or “hot carriers” and collide with a lattice site of the semiconductor material and lose energy.

Solar cells made of higher band gap semiconductor can absorb more photons and generates more electricity.

### SUMMARY

According to embodiments, a band gap of a semiconductor material within a photovoltaic (PV) solar cell can be modified by application of electric pulses. Such modification can produce more electricity in response to received light.

According to embodiments, application of electric pulses to a PV semiconductor material can provide a way to extract highly energetic or “hot” carriers resulting from incident light. For example, highly energetic electric pulses can force the hot electrons to be collected by the electrode instead of losing their energy to a lattice site.

According to embodiments, high frequency and high energy electric pulses can alter the band gap of semiconductor temporarily and dynamically.

According to embodiments, pulses of several kilowatts, or more, of power can be applied to a semiconductor based solar cell to alter its behavior by altering the band gap of the semiconductor material. An altered band gap semiconductor can absorb an altered number of photons of light and therefore produce different energy as compared to the semiconductor material alone.

According to embodiments, high frequency electric pulses applied to a PV solar cell semiconductor material can carry large amounts of power per pulse. For example, a pulse can be about 30 V, 2 A and 1 MHz, for a pulse that carries about 60 megawatts per pulse.

According to embodiments, high frequency electric pulses can be generated from a stack of pyroelectric thin films.

According to embodiments, pyroelectric films coated on a transparent substrate (e.g., glass) can produce high frequency electric pulses upon being subjected to bias voltage from the solar cell. In particular embodiments, pulse shaping circuits and a timing device can be used to shape the electric pulses. In very particular embodiments, a timer and relay can be employed. In some embodiments, pulse shaping capacitors and pyroelectric thin films coated on glass can be electrically connected in parallel.

### BRIEF DESCRIPTION OF THE DRAWINGS

The embodiments disclosed are shown by way of example and not limitation in the described figures. In the described figures, like reference indicate similar elements.

FIG. 1 is a block diagram of a solar energy generating system according to an embodiment.

FIG. 2 is a block diagram of a solar energy generating system according to another embodiment.

FIG. 3 is a block diagram of a pulse generator according to an embodiment.

FIG. 4 is a side cross sectional representation of pyroelectric materials that can form part of a pulse generator according to an embodiment.

FIG. 5 is a block schematic diagram of a pulse generator according to another embodiment.

FIGS. 6A to 6C are diagrams showing the generation of electric pulses with pyroelectric materials that can be included in embodiments.

FIG. 7 is a diagram showing the generation of a hot electron in PV solar cell material.

FIG. 8A is a diagram showing how the energy of a hot carrier can be lost by collision within a semiconductor lattice of a photovoltaic (PV) solar cell. FIG. 8B is a diagram showing how a hot carrier can be collected in a PV solar cell according to an embodiment.

FIG. 9 is a diagram showing how the energy of a hot carrier can be lost to thermalization in a semiconductor material of a PV solar cell.

FIG. 10 is a graph showing electron energy loss to thermalization in PV solar cell versus the wavelength of an incident photon.

FIG. 11 is a graph showing how conduction in an indirect semiconductor can be assisted by phonon action.

FIG. 12 is a diagram representing a band gap of an indirect semiconductor material that includes both an electronic band gap, as well as a “phonon” band gap.

FIG. 13 is a diagram showing how the electronic and phonon band gap can be modified by application of electric pulses to the semiconductor material.

FIGS. 14A and 14B are diagrams showing how electric pulses can increase the conductivity of carriers within a semiconductor material.

FIG. 15 is a graph showing of simulation results demonstrating how application of voltage pulses can increase the current output of a PV solar cell.

FIG. 16 is a graph showing an electron-lattice collision time versus the wavelength of an incident photon.

### DETAILED DESCRIPTION

Embodiments disclosed herein show systems and methods in which a band gap of a semiconductor within a photovoltaic (PV) solar cell is modified using electric pulses. Such modification can produce more electricity from the solar cell as compared to its operation with an unmodified band gap. In some embodiments, high energy electric pulses applied to a solar cell can enable the extraction of highly energetic (e.g., hot carrier) electrons (or holes) that might otherwise be lost (e.g., by collisions within the crystal lattice of the semiconductor).

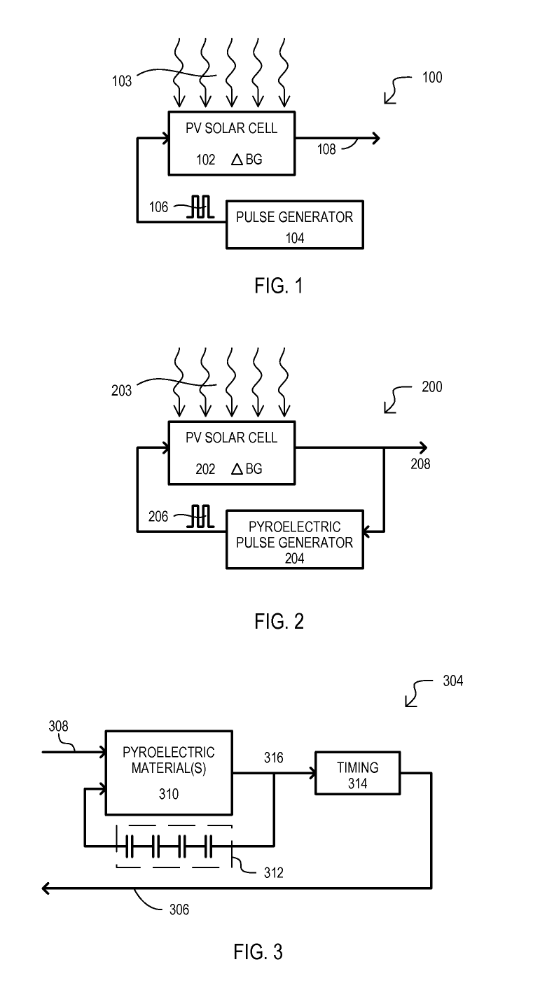

FIG. 1 shows a system 100 according to one embodiment. A system 100 can include a PV solar cell 102 and a pulse generator 104. A PV solar cell 102 can include one or more semiconductor materials having a p-n junction formed therein. The semiconductor material(s) can have a band gap. Incident light 103 (e.g., sunlight) can provide photons which generate electrons (and holes) to produce output power 108 from the PV solar cell 102.

A pulse generator 104 can generate electric pulses 106 that are applied to the semiconductor material of PV solar cell 102 to thereby alter the band gap (ΔBG) of the semiconductor material(s). It is understood that the symbol for the electric pulses 106 is representational, and not intended to imply any particular pulse shape. Pulse shape, frequency and magnitude can vary according to various factors, including materials used, desired output power, and operating conditions, to name a few.

According to some embodiments, electric pulses 106 applied to PV solar cell 102 can be high frequency and high energy pulses. A high frequency pulse can be a pulse greater than 100 kHz, in some embodiments greater than 500 kHz, and in particular embodiments about 1 MHz A high energy pulse can provide no less than 500 Watts, in some embodiments, no less than a kilowatt (kW), and in particular embodiments no less than a few kW.

In response to the application of electric pulses 106 to the semiconductor material(s) within the PV solar cell 102, a band gap of such semiconductor material(s) can be modified. Consequently, the PV solar cell 102 can generate electron/holes from photons having a different energy (as compared to when pulses are not applied). In addition or alternatively, a modification of the semiconductor material(s) band gap can enable the absorption of high energy or “hot” carriers by the PV solar cell 102 (i.e., such hot carriers contribute to the current generated). In this way, the power 108 generated by the PV solar cell 102 can be increased or otherwise modified.

According to some embodiments, electric pulses applied to a PV solar cell can be generated by the use of one or more pyroelectric materials. Pyroelectric materials can generate electric energy (e.g., temporary voltage) when they are subjected to a change in temperature (e.g., heated or cooled). However, in addition, when an electric field is applied to a pyroelectric material, a temperature gradient can be produced (i.e., a reverse pyroelectric effect). In particular embodiments, a temperature gradient in one pyroelectric material produces an electric field, and such an electric field can be used to polarize a second pyroelectric material. The second pyroelectric material can be discharged, and then the process can repeat itself.

Such operations can create an oscillating electric field (i.e., electric pulses). Such pulses can be conditioned (e.g., shaped, grouped, amplified, reduced, or modulated) before being applied to a PV solar panel.

FIG. 2 shows a system 200 according to another embodiment. A system 200 can include items like those of FIG. 1, however, a pulse generator 204 can be a pyroelectric based pulse generator. That is, pulses generated by pulse generator 204 can be derived from one or more pyroelectric materials.

A PV solar cell 202 can operate in a fashion like 102 of FIG. 1, including having semiconductor material(s) with band gaps that are modified by application of electric pulses.

A pyroelectric based pulse generator 204 can generate pulses based on one or more pyroelectric materials. As noted above, in some embodiments, different pyroelectric materials can be used in combination, along with an applied voltage source to generate an oscillating signal from such pyroelectric materials. In the embodiment shown, output 208 of PV solar cell 202 can be applied to pyroelectric material(s) within the pulse generator 204 to polarize the material. While embodiments can include multiple pyroelectric materials, a pyroelectric based pulse generator 204 could include one such material operating in combination with other materials or circuits to generate a pulse.

FIG. 3 is a block schematic diagram of a pulse generator 304 according to one particular embodiment. A pulse generator 304 can include pyroelectric material(s) section 310, pulse shaping circuit 312, and a timing circuit 314. Pyroelectric material(s) section 310 can include one or more pyroelectric materials that are used to generate electric pulses for application to a PV solar cell. It is understood that pyroelectric material(s) section 310 can include multiple pyroelectric materials with different dielectric constants, first pyroelectric material(s) operating according to a pyroelectric effect (i.e., generating a potential in response to a temperature gradient) while second pyroelectric material(s) can be polarized by the first pyroelectric material(s). A resulting oscillating electric field can generate initial electrical pulses 316.

A pulse shaping circuit 312 can shape initial electric pulses 316 and feed them back to the pyroelectric material(s) section 310. In this way, electric pulses can be generated having a desired duration and/or magnitude and/or polarity. While the embodiment of FIG. 3 depicts a pulse shaping circuit 312 as a capacitance in parallel with pyroelectric material(s) section 310, it is understood that a pulse shaping circuit 312 can include any suitable passive or active circuit elements to generate a desired pulse shape. In addition or alternatively, pulse shaping circuit 312 can shape pulses in a dynamic fashion, according to operating conditions of a system. As but two examples, pulse shaping can vary according to a detected temperature and/or a received output voltage of a PV solar cell.

A timing circuit 314 can alter or otherwise control pulses 316 output from pyroelectric material(s) section 310, to generate input electric pulses 306 for application to semiconductor material(s) within a PV solar cell (e.g., to thereby alter the band gap of such materials).

The pulse generator of FIG. 3 is provided by way of example, and should not be construed as limiting.

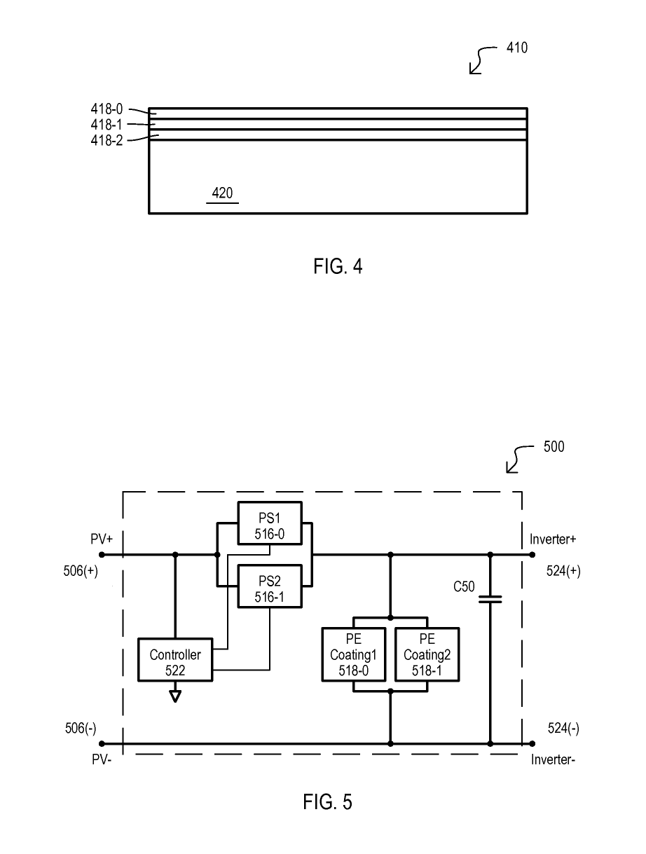

FIG. 4 is a side cross sectional view of pyroelectric materials 410 that can be included in embodiments. Pyroelectric materials 410 can be used to generate electric pulses as described herein, or equivalents. Pyroelectric materials 410 can include a number of pyroelectric thin films 418-0 to 418-2 (in the embodiment shown, three layers) formed on a substrate 420. In particular embodiments, pyroelectric thin films (418-0 to 418-2) can each be formed of different pyroelectric materials having different dielectric constants. It is noted that one or more and of the pyroelectric thin films (418-0 to 418-2) may not be polarized, but can behave as a good pyroelectric material upon being electrically biased (e.g., by application of PV solar cell output voltage).

Accordingly, in some embodiments, while a PV solar cell operates in response to photons received from sunlight, pyroelectric materials 410 can operate in a pyroelectric fashion in response to heat from the sunlight, as well as be polarized upon being subjected to an electric field (i.e., a “reverse” pyroelectric effect). The generated pulses can be applied to a PV solar cell to vary the band gap of its materials.

FIG. 5 is a block schematic diagram of a system 500 according to another embodiment. A system 500 can be connected to a PV solar cell (not shown) at PV connections 506(+) and 506(−) and to an inverter (not shown) at inverter connections 524(+) and 524(−). A system 500 can include pulse shaping circuits 516-0 and 516-1, a controller 522, pyroelectric materials 518-0 and 518-1 (e.g., thin films or coatings), and a capacitor C50.

According to well understood techniques, an inverter provided at connections 524(+) and 524(−) can generate an AC current/voltage an output of PV solar cell (in this case via pulse shaping circuits (516-0 and 516-1)).

Pulse shaping circuits (516-0 and 516-1) can provide frequency modulation to electric pulses created by pyroelectric materials (518-0 and 518-1). A controller 522 can enable modification of the electric pulses generated by the pulse shaping circuits (516-0 and 516-1), including but not limited to, modifying pulse shape, height (i.e., magnitude), width (i.e., duration), and time between consecutive pulses that are used to modulate the pulses provided by pyroelectric materials (518-0 and 518-1). In a particular embodiment, one pulse shaping circuit (e.g., 516-0) modulates electric pulses going into the PV solar cell while the other (e.g., 516-1) modulates electric pulses coming out of the PV solar cell.

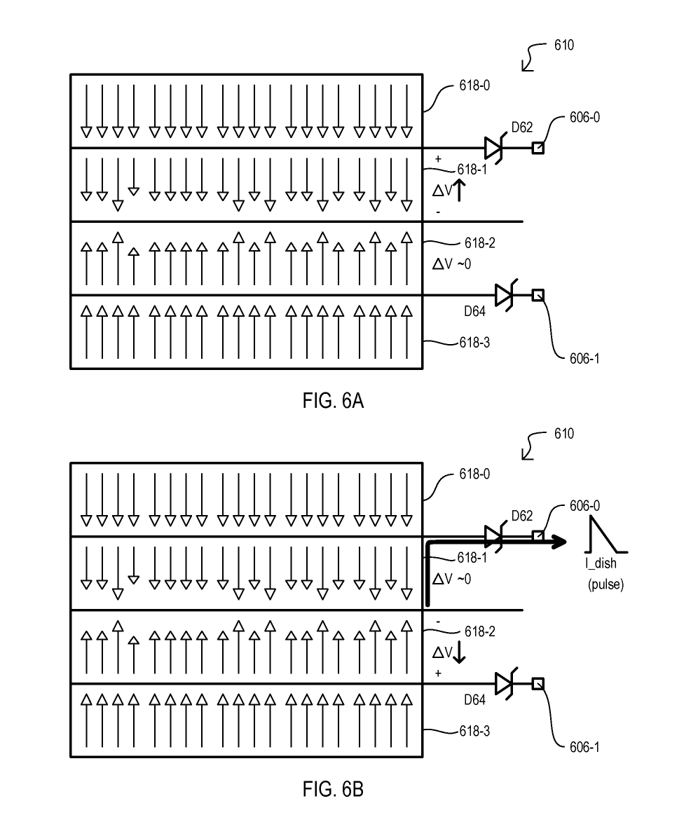

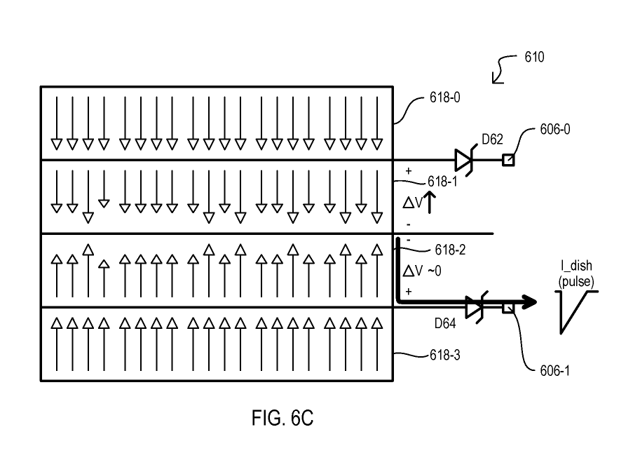

In embodiments described herein, the generation of electric pulses from one or more pyroelectric materials can be according to any suitable method. One very particular embodiment for extracting electric pulses is shown in FIG. 6A to 6C.

FIGS. 6A to 6C show a block diagram of a pyroelectric materials subsystem 610 according to an embodiment. Subsystem 610 can include pyroelectric materials 618-0 to 618-3 and diodes D62 and D64. Optionally, in the event the subsystem 610 is utilized to harvest energy from the pyroelectric materials (618-0 to 618-3), the subsystem 610 could also include a rectifier circuit (not shown) to capture alternating pulses at pulse outputs 606-0 and 606-1.

Pyroelectric materials (618-0 to 618-3) can be pyroelectric layers formed on a substrate. In such an arrangement, pyroelectric layers 618-0 and 618-1 can be top layers, while pyroelectric layers 618-2 and 618-3 can be bottom layers. That is, the pyroelectric layers (618-0 to 618-3) can be formed on a substrate (e.g., glass), but top pyroelectric layers (618-0 and 618-1) can be formed over bottom pyroelectric layers (618-2 and 618-3).

In general, subsystem 610 relies on a pair of pyroelectric layers (e.g., 618-1/2). A first pyroelectric layer can be polarized when subject to heat and/or induction from another layer. The electric layer field produced in the first pyroelectric layer can be used to reduce the electric field from a second pyroelectric layer. The first pyroelectric layer can then be discharged, to create an electric pulse, for example. Subsequently, the second pyroelectric layer can then be polarized when subject to heat and/or induction from another layer. The electric layer field produced in the second pyroelectric layer can be used to reduce the electric field in the first pyroelectric layer. The second pyroelectric layer can then be discharged, to create an electric pulse, for example. These processes can then repeat.

FIGS. 6A to 6C show pulse generating operations according to a particular embodiment. In FIG. 6A, pyroelectric layer 618-2 can be initially discharged by a system 610, and thus have little or no polarization. In response to induction from pyroelectric layer 618-0, pyroelectric layer 618-1 can polarize, to increase the charge generated by the layer.

FIG. 6B shows how pyroelectric layer 618-1 can be discharged to generate a pulse. Once a voltage across pyroelectric layer 618-1 exceeds a predetermined limit (in this case a Schottky diode threshold voltage), the layer can be discharged. While the embodiment of FIG. 6B utilizes a diode to extract charge from a polarized pyroelectric layer, any other suitable method can be employed. Subsequently, in response to induction from pyroelectric layer 618-3, pyroelectric layer 618-2 can polarize, to increase the charge generated by the layer.

FIG. 6C shows how pyroelectric layer 618-2 can be discharged to generate a pulse. Once a voltage across pyroelectric layer 618-2 exceeds a predetermined limit, the layer can be discharged.

As noted above, according to some embodiments, the application of electric pulses to a semiconductor within a PV solar cell can enable the capture of hot carriers that would otherwise be lost.

FIG. 7 is a diagram showing how a conventional PV solar cell will lose the energy of a hot carrier. FIG. 7 shows a PV solar cell 702 with a semiconductor material having a valence band 728 and a conduction band 730. A photon 703-0 having appropriate energy can excite an electron 732-0 in the valence band 728 so that it jumps to the conduction band 730. However, higher energy photon 703-1 can generate a hot carrier, in this case an electron 732-1, which can enter a higher energy state. Such an electron can lose some or all of its energy by collisions within a lattice.

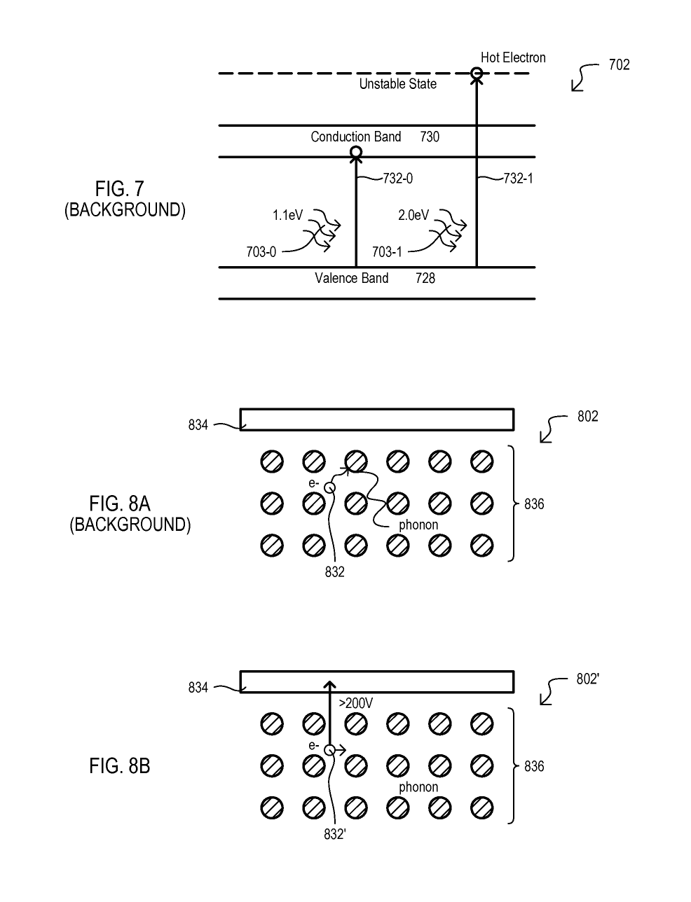

FIG. 8A is a diagram of a PV solar cell 802 having an electrode 834 and crystal lattice 836. A hot carrier (in this case electron 832) can be generated by an incident photon of sufficient energy. As shown, the electron 832 can collide with a lattice site to generate a phonon. A phonon represent the thermalization of the hot carrier energy, resulting in the electron 832 failing to flow to the electrode 834.

FIG. 8B is a diagram of a PV solar cell 802′ operating according to an embodiment. Unlike FIG. 8A, PV solar cell 802′ can be biased with a relatively large electric pulse. Consequently, a hot carrier (in this case electron 832) can be attracted to an electrode 834 before colliding with a lattice site. In some embodiments, an electric pulse can be generated with one or more pyroelectric materials.

Having described the absorption of hot carriers according to an embodiment, various aspects of hot carriers will now be discussed. A semiconductor material of a PV solar cell can have a band gap given by E_{g}. An incident photon can have an energy of Eₚₕ=hυ=hc/λ; where h=Planck's constant, υ=frequency of light, c=the speed of light, and λ=wavelength of the light. If Eₚₕ>E_{g}, an electron-hole pair can be generated in the semiconductor material. The kinetic energy of the electron (of mass mₑ and velocity vₑ) can be given by,

½mₑvₑ²=(hv−Eg)

which can yield an electron velocity (vₑ) of

$${v}_{e} = \sqrt{\frac{2 ( hv - {E}_{g} )}{{m}_{e}}} .$$

An electron can lose excess energy by collisions with a lattice to generate lattice vibrations (thermalization). An average energy of an electron after thermalization can be given by E_{g}+3kT/2, where k is the Boltzmann constant and T temperature. Thus, energy lost by an electron due to thermalization can be given as:

ΔE=hv−(E_{g}+3/2kT)

From this, the average power lost due to heat in a conventional PV solar cell can be:

$${P}_{H} = ( \frac{{P}_{L}}{hv} ) Δ E$$

where PL is the power of the incident light.

As a particular example, silicon can have a band gap of 1.12 eV and red light from the solar spectrum can have λ=650 nm. In such an arrangement the average energy of electrons after thermalization can be:

E_{avg}=(E_{g}+3kT/2)=1.12 eV+(3/2)(0.0259)eV=1.16 eV

The energy of an incident photon can be

$$hv = \frac{hc}{λ} = 1.91 eV$$

and the energy lost be each incident electron can be

ΔE=hv−(E_{g}+3/2kT)=1.91eV−1.16 eV=0.75 eV

and given an average power P_{L}=1.35 kW/m², the average dissipated power can be

P_{H}=((1.35 kW/m²)/1.91 eV)*(0.75 eV)=0.53 kW/m².

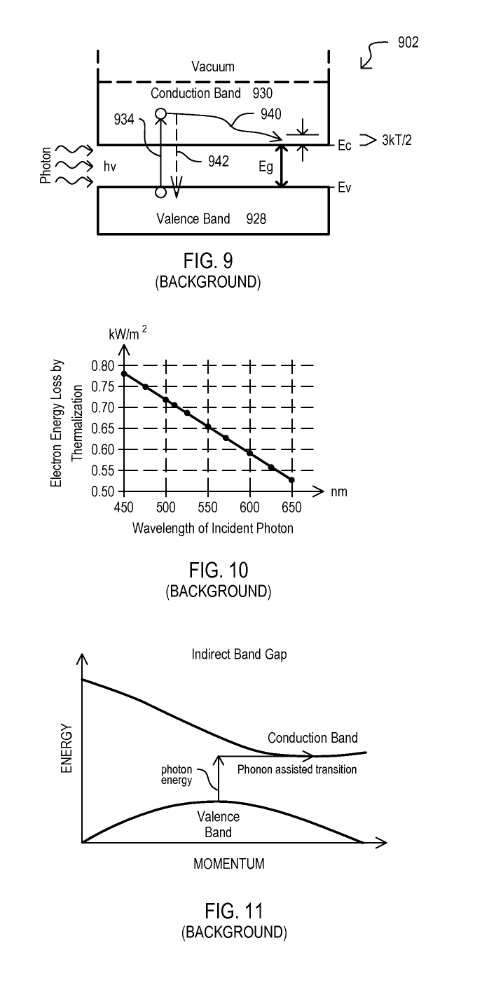

FIG. 9 is a diagram showing the hot carrier mechanism in a semiconductor material. A hot carrier 934 can be generated that exits the valence band 928 and enters a high energy state. In some cases, due to thermalization, a hot carrier 934 can lose essentially all of its energy via path 942, and thus never contribute to a PV solar cell current. In other cases, the hot carrier 934 may lose less energy (e.g., 3/2kT, as described above), to remain in the conduction band 930.

FIG. 10 is a graph showing electron loss due to thermalization versus a wavelength of the incident light for silicon as the semiconductor material.

As shown above, in a PV solar cell semiconductor material, excess energy (i.e., energy beyond the band gap) can be lost as phonons in lattice collisions. However, appropriate phonons can be used to increase the life of hot carriers, to enable the capture of more hot carriers. In an indirect band gap semiconductor, such as silicon, phonons can be involved in band to band transitions of an electron. This is shown in FIG. 11. A carrier can be generated by a photon, and can transition from a valence band to the conduction with the assistance of a phonon in order to conserve momentum.

From the above, it is understood that a semiconductor material can be conceptualized as including both an electronic band gap as well as a “phonon band gap”. The electronic band gap arises from interaction between periodic electrostatic forces within a lattice. At the same time, a phonon band gap can also exist within a semiconductor material due to mechanical movement within lattice sites.

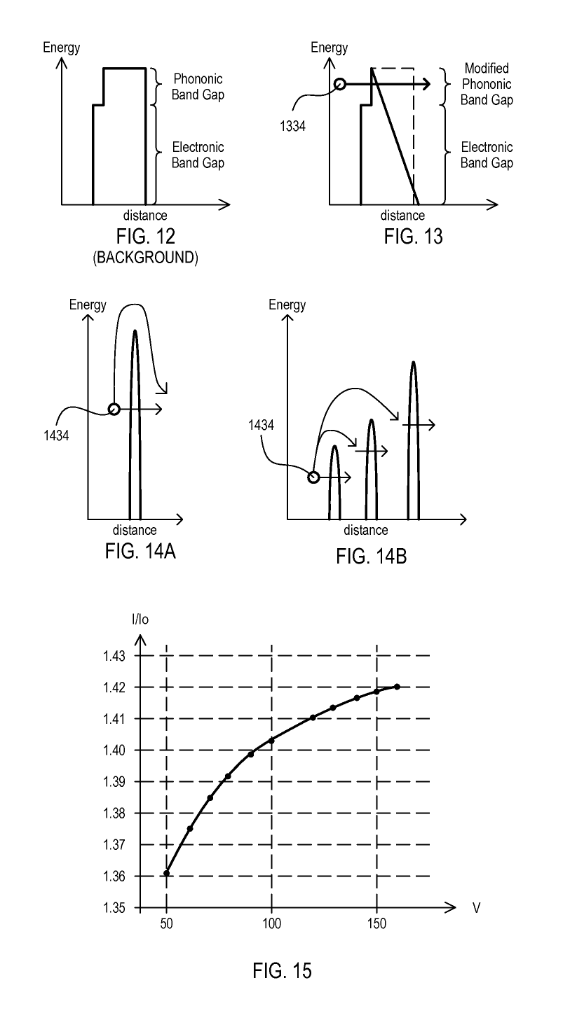

FIG. 12 is a diagram representing a potential barrier arising from both an electronic band gap and phononic bad gap. FIG. 13 shows how the application of an electric voltage pulse can bend the potential barrier, allowing more (or increasing the probability) of such carriers (e.g., 1334) passing through the quantum mechanical barrier presented by the band gaps.

FIG. 14A is a diagram showing how an electric pulse can enable a carrier (1434) to pass a band gap barrier. FIG. 14B is a diagram showing sequence of modified bad gaps resulting from a sequence of electric pulses.

FIG. 15 is a graph showing simulation results that demonstrate an increase in output current of a PV solar cell versus the amplitude of electric pulses applied to the cell. “I” is the increased output current, and “Io” is a baseline current (a current absent the electric pulses).

According to embodiments, the thermalization of carriers can be slowed by application of electric pulses. By way of example, a lattice (e.g., silicon lattice) can have a lattice constant given by a₀. Thus, the maximum distance travelled by a photon generated carrier (e.g., electron) can be a₀. A travel time of a carrier with a velocity vₑ before it reaches a lattice site can be given by

$$\begin{matrix}{t}_{H} = {a}_{0} / {v}_{e} . \\ = {a}_{0} \sqrt{\frac{{m}_{e}}{2 ( hv - {E}_{g} )}} \\ = {a}_{0} \sqrt{\frac{{m}_{e}}{2 ( hc / λ ) - {E}_{g}}}\end{matrix}$$

where mₑ is the mass of the carrier. Using the above relationship, assuming a silicon lattice (a₀=5.43×10⁻¹⁰ m, E_{g}=1.12 eV) and red light (λ=6×10⁻⁷ m), a carrier travel time will be t_{H}=1.03 femtoseconds (fs).

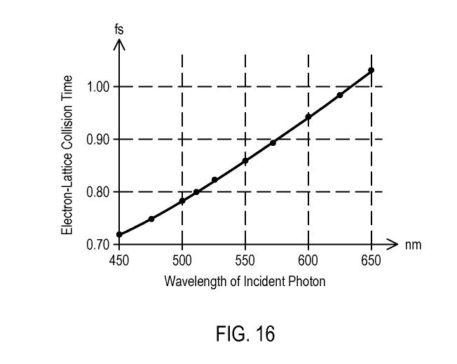

FIG. 16 is a graph showing simulated electron travel times in a silicon lattice versus the wavelength of incident light.

While embodiments herein have disclosed particular semiconductor materials and electric pulse generating methods and circuits, such particular embodiments should not be construed as limiting. Alternate embodiments can include different materials and/or any suitable electric pulse duration, amplitude, waveshape, etc.

It should be appreciated that reference throughout this description to “one embodiment” or “an embodiment” means that a particular feature, structure or characteristic described in connection with the embodiment is included in at least one embodiment of an invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

It is also understood that other embodiments of this invention may be practiced in the absence of an element/step not specifically disclosed herein. Further, while embodiments can disclose actions/operations in a particular order, alternate embodiments may perform such actions/operations in a different order.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claims require more features than are expressly recited in each claim. Rather, inventive aspects lie in less than all features of a single foregoing disclosed embodiment. Thus, the claims following the detailed description are hereby expressly incorporated into this detailed description, with each claim standing on its own as a separate embodiment of this invention.

What is claimed is:

1. A system, comprising:
at least one solar cell comprising a semiconductor material having p-n junctions formed therein; and
a pulse generator electrically coupled to the solar cell and configured to apply electric pulses to dynamically alter a band gap of the semiconductor material as photons are received by the semiconductor material.

2. The system of claim 1, wherein:
the pulse generator comprises at least one pyroelectric material that generates an electric potential in response to a temperature gradient, the electric potential applied to form at least a portion of the electric pulses applied to the semiconductor material.

3. The system of claim 2, wherein:
the pulse generator comprises a plurality of different pyroelectric materials.

4. The system of claim 2, wherein:
the pulse generator includes a pulse shaping circuit configured to shape the electric pulses and apply shaped electric pulses back to at least one pyroelectric material.

5. The system of claim 2, wherein:
the pulse generator comprises a plurality of different pyroelectric material films formed on a transparent substrate.

6. The system of claim 2, wherein:
the pulse generator comprises at least three pyroelectric material films formed on top of one another, at least two of the pyroelectric material films having different dielectric constants.

7. The system of claim 2, wherein:
the pulse generator further includes at least one pulse shaping circuit to shape pulses generated with the at least one pyroelectric material, and apply such shaped pulses to the semiconductor material of the solar cell.

8. A system, comprising:
at least one solar cell comprising a semiconductor material having p-n junctions formed therein; and
a pulse generator electrically coupled to the solar cell comprising at least one pyroelectric material that generates an electric potential in response to a temperature gradient, the electric potential forming at least a portion of electric pulses applied to the semiconductor material as photons are received by the semiconductor material.

9. The system of claim 8, wherein:
the electric pulses have a frequency of no less than 100 kHz.

10. The system of claim 9, wherein:
the electric pulses have a frequency of no less than 500 kHz and a magnitude of no less than 10V.

11. The system of claim 9, wherein:
each electric pulse has no less than 1 mega Watt of power.

12. The system of claim 8, wherein:
the pulse generator is coupled between the at least one solar cell and connection to an inverter circuit.

13. The system of claim 12, wherein:
the pulse generator includes
at least two pulse shaper circuits coupled in parallel between a first solar cell output and a first inverter input, and
at least two different pyroelectric materials coupled in parallel to the first inverter input.

14. The system of claim 8, wherein:
the at least one pyroelectric material comprises a plurality of different pyroelectric materials layers formed on top of one another on a transparent substrate.

15. A method, comprising:
generating electric pulses from at least one pyroelectric material;
applying the electric pulses to at least one photovoltaic solar cell as the solar cell receives photons; and
generating electric power from the solar cell.

16. The method of claim 15, wherein:
generating the electric pulses includes generating the electric pulses with a plurality of pyroelectric materials having different dielectric constants.

17. The method of claim 15, wherein:
generating the electric pulses includes generating the electric pulses with a plurality of pyroelectric material films formed on a transparent substrate.

18. The method of claim 15, wherein:
generating the electric pulses includes shaping initial electric pulses from the at least one pyroelectric material with pulse shaping circuits to generate the electric pulses.

19. The method of claim 15, wherein:
generating the electric pulses includes applying an output voltage from the solar cell to the at least one pyroelectric material.

20. The method of claim 15, further including:
shaping initial electric pulses from the at least one pyroelectric material and applying the shaped electric pulses back to the at least one pyroelectric material.
